(19) United States
(12) Patent Application Publication
(10) Pub. No.: US 2008/0179638 A1
(43) Pub. Date: Jul. 31, 2008

(54) GAP FILL FOR UNDERLAPPED DUAL STRESS LINERS

(75) Inventors: Thomas W. Dyer, Pleasant Valley, NY (US); Sunfei Fang, Lagrangeville, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/669,287

(22) Filed: Jan. 31, 2007

(51) Int. Cl. H01L 29/94; H01L 21/336

(52) U.S. Cl. 257/288; 438/197

(57) ABSTRACT

A gap fill nitride is formed in an underlapping region between a first semiconductor area with a first stress liner and a second semiconductor area with a second stress liner without plugging other tightly spaced structures. This is achieved by filling the tightly spaced structures with middle-of-line dielectric material such as silicon oxide in both the first and the second semiconductor areas prior to the formation of the gap fill nitride. The combination of the first and second stress liners and the gap fill nitride provides a continuous mobile ion diffusion barrier across the entire surface of a CMOS semiconductor structure.

### FIELD OF THE INVENTION

The present invention relates to a semiconductor structure and method of manufacturing the same, and particularly to a semiconductor structure with a gap fill for underlapped dual stress liners and methods of manufacturing the same.

### BACKGROUND OF THE INVENTION

Mobility of minority carriers in a metal oxide semiconductor field effect transistor (MOSFET) may be manipulated by stress applied to the channel of the MOSFET. However, the response of the mobility to an applied stress is dependent on the carrier type. In the case of a silicon channel MOSFET, a compressive stress on the channel increases the mobility of holes and decreases the mobility of electrons while a tensile stress on the channel increases the mobility of electrons and decreases the mobility of holes.

The opposite response of the mobility of the two types of carriers to a stress applied to the channel of a MOSFET has led to the use of dual stress liners to enhance the performance of both p-type MOSFETs and n-type MOSFETs. In typical dual stress liner schemes, a first stress liner is deposited over a first semiconductor area to increase the mobility of the minority carriers in the first type MOSFET devices, and subsequently a second stress liner is deposited over a second semiconductor area to increase the mobility of the minority carriers in the second type MOSFET devices. The first semiconductor area and the second semiconductor area are complementary areas of the semiconductor substrate separated by shallow trench isolation. The first type MOSFET and the second type MOSFET are of opposite types, i.e., one is of p-type and the other is of n-type. Consequently, the first stress liner and the second stress liner apply opposite types of stress to the channels of the underlying MOSFETs.

In general, each semiconductor area has only one type of stress liner. Some difficulties arise at the boundaries of two semiconductor areas of opposite types since one type of stress liner needs to be phased out and the other type of stress liner needs to be phased in. However, gradual thinning of a film is difficult to achieve in semiconductor processing. Furthermore, a masking step has an inherent overlay tolerance, which makes formation of coincident edges of both stress liners at the boundary very difficult.

According to a first prior art, the two adjoining stress liners overlap at the boundary. Sequential vertical cross-sections of a first prior art structure are shown in FIGS. 1A-3A and 1B-3B. Figures identified with a suffix “A” are vertical cross-sections of the first prior art structure at a location with a gate conductor 22 over shallow trench isolation 12. Figures identified with a suffix “B” are vertical cross-sections of the first prior art structure at a location without a gate conductor 22 over the shallow trench isolation 12. Figures with the same figure numeral refer to the same stage of manufacture.

Referring to FIGS. 1A and 1B, first type MOSFETs and second type MOSFETs comprise portions of the semiconductor substrate 10, a gate dielectric 20, patterned gate conductors 22, gate spacers 24, gate silicide 26, and source and drain silicide 16. A gate line comprising a gate conductor 22, gate spacers 24, and gate silicide 26 is also shown in FIG. 1A over shallow trench isolation 12. A first stress liner 30, and optionally and preferably a first etch stop layer 32 are deposited and patterned with a first photoresist (not shown) such that the first stress liner 30 and the optional first etch stop layer 32 remain over first type MOSFETs, which are located within a first semiconductor area 1, and are removed from above the second type MOSFETs, which are located within a second semiconductor area 2. As shown in FIG. 1A, if a gate conductor 22 is located near a boundary between the first semiconductor area 1 and the second semiconductor area 2, only a portion of the gate conductor 22 is covered with the first stress liner 30 and the optional first etch stop layer 32. The portion of the gate line over shallow trench isolation 12 that is covered with the first stress liner 30 and the optional first etch stop layer 32 is at least as wide as the overlay tolerance of a block mask to be subsequently used.

According to the first prior art, a second stress liner 40 is deposited and lithographically patterned with a second photoresist 41 and a block mask such that the second semiconductor area 2 and the boundary between the first semiconductor area 1 and the second semiconductor area 2 are covered with the second photoresist 41 as shown in FIGS. 2A and 2B. The edge of the photoresist 41 is displaced from the edge of the patterned first stress liner 30 toward the first semiconductor area 1.

The exposed portion of the second stress liner 40 is thereafter etched and the second photoresist 41 is removed to produce a structure shown in FIGS. 3A and 3B. The resulting structure has an overlapping portion 40′ of the second stress liner 40 that is located either directly on the optional first etch stop layer 32 or directly on the first stress liner 30.

According to the first prior art structure shown in FIGS. 3A and 3B, overlapping transition regions containing an overlapping portion 40′ of the second stress liner 40 are formed between the first semiconductor area 1 and the second semiconductor area 2. The overlapping transition region comprises a stack of the second stress liner 40, the optional first etch stop layer 32, and the first stress liner 30. Typically, the first stress liner 30 and the second stress liner 40 are different types of silicon nitrides and the optional first etch stop layer 32 may be a silicon oxide layer. The stack within the overlapping transition region poses a significant challenge to a subsequent contact etch process due to the increased thickness and the variety of layers in the stack.

Typically, the first stress liner 30 and the second stress liner 40 are different types of silicon nitride layers and collectively form a mobile ion barrier layer. While consideration has been given to eliminating the overlapping portion 40′ by intentionally underlapping the stress liners (30, 40), strictly underlapping stress liners (30, 40) are unacceptable since they would result in a discontinuity in the barrier layer, thereby allowing mobile ions to diffuse through from back-end-of-line dielectric (BEOL) layers and from middle-of-line (MOL) layers, and causing reliability problems.

According to a second prior art, underlapped stress liners with a nitride gap fill process is employed in order to plug the gap between the two liners and to provide a continuous diffusion barrier. An exemplary structure according to the second prior art is shown in FIGS. 4A-8A and 4B-8B. Figures identified with a suffix “A” are vertical cross-sections of the second prior art structure at a location with a gate conductor 22 over shallow trench isolation 12. Figures identified with a suffix “B” are vertical cross-sections of the second prior art structure at a location without a gate conductor 22 over shallow trench isolation 12. Figures with the same figure numeral refer to the same stage of manufacture.

Referring to FIGS. 4A and 4B, first type MOSFETs and second type MOSFETs comprise portions of the semiconductor substrate 10, a gate dielectric 20, patterned gate conductors 22, gate spacers 24, gate silicide 26, and source and drain silicide 16. A gate line comprising a gate conductor 22, gate spacers 24, and gate silicide 26 is also shown in FIG. 4A over shallow trench isolation 12. A first stress liner 30, and optionally and preferably a first etch stop layer 32 are deposited and patterned with a first photoresist (not shown) such that the first stress liner 30 and the optional first etch stop layer 32 remain over first type MOSFETs, which are located within a first semiconductor area 1, and are removed from above the second type MOSFETs, which are located within a second semiconductor area 2. As shown in FIG. 4A, if a gate conductor 22 is located near a boundary between the first semiconductor area 1 and the second semiconductor area 2, only a portion of the gate conductor 22 is covered with the first stress liner 30 and the optional first etch stop layer 32. The exposed portion of the gate line over shallow trench isolation 12 is at least as wide as the overlay tolerance of a block mask to be subsequently used.

According to the second prior art, a second stress liner 40 and optionally, but preferably, a second etch stop layer 42 is deposited and lithographically patterned with a second photoresist 43 such that the second semiconductor area 2 is covered with the second photoresist 41. However, unlike the first prior art, the edge of the first stress liner 30 and the optional first etch stop layer 32, located over the shallow trench isolation between the first semiconductor area 1 and the second semiconductor area 2, is not covered with the second photoresist 43 as is shown in FIGS. 5A and 5B. In other words, the edge of the photoresist 43 is displaced from the edge of the patterned first stress liner 30 toward the second semiconductor area 2.

The exposed portions of the optional second etch stop layer 42 and the second stress liner 40 are thereafter etched and the second photoresist 43 is removed to produce a structure shown in FIGS. 6A and 6B. The resulting structure has an underlapping portion at the boundary between the first semiconductor area 1 and the second semiconductor area 2 such that neither the first stress liner 30 nor the second stress liner 40 is present over shallow trench isolation 12 or over a gate silicide 26.

According to the second prior art, a gap fill nitride 50 is deposited over the first stress liner 30 and over the second stress liner 40 as shown in FIGS. 7A and 7B. An undesirable consequence of such a gap fill process is that gaps between tightly spaced gate conductors 22 are also plugged at the same time that the gap between the first and second stress liners (30, 40) is plugged.

Even etchback of the gap fill nitride 50, as shown in FIGS. 8A and 8B, does not remove the material that plugs the gaps between tightly spaced gate conductors 22. While the remaining gap fill nitride 50′ after the etchback process plugs the gap at the boundary between the first semiconductor area 1 and the second semiconductor area 2, gaps between any other tightly spaced structures are also plugged up by the remaining gap fill nitride 50′ as well. Since nitrides are difficult to etch than other dielectric material such as an oxide, which is a typical material for a MOL dielectric, the second prior art creates additional contact etch problems in other locations of the semiconductor structure, i.e., inside the first and second semiconductor area (1, 2), while solving the contact etch problem at the boundary between the first and the second semiconductor areas (1, 2).

Therefore, there exists a need for a semiconductor structure and methods of manufacturing the same that reduces or eliminates difficulties in contact etch process due to thickness and/or composition variations of stress liners across a complementary metal-oxide-semiconductor (CMOS) semiconductor structure.

Furthermore, there exists a need for a semiconductor structure and methods of manufacturing the same that provides the above benefit providing a continuous mobile ion diffusion barrier across the entire surface of a CMOS semiconductor structure while preventing gap fill of tightly spaced structures elsewhere by materials that are hard to etch such as a nitride.

### SUMMARY OF THE INVENTION

The present invention addresses the needs described above by providing a semiconductor structure with a gap fill nitride in an underlapped region between two stress liners while preventing plugging of gaps between tightly spaced structures with a nitride and methods for manufacturing the same.

The present invention also provides a coverage of the entire surface of a semiconductor structure with a continuous mobile ion diffusion barrier that comprises a first stress liner, a second stress liner, and a gap fill nitride and methods for manufacturing the same.

According to the present invention, a semiconductor structure comprises:

a semiconductor substrate;

at least one first type MOSFET located in a first semiconductor area on the semiconductor substrate;

a first stress liner located directly on the at least one first type MOSFET;

at least one second type MOSFET located in a second semiconductor area on the semiconductor substrate;

a second stress liner located directly on the at least one second type MOSFET;

an underlapping region located between the first semiconductor area and the second semiconductor area, wherein neither the first liner nor the second liner is present;

a gap fill nitride located in the underlapping region; and

at least one tightly spaced gap structure in a location selected from the group consisting of a first location between two substantially vertical walls of the first stress liner in the first semiconductor area and a second location between two substantially vertical walls of the second stress liner in the second semiconductor area; wherein the at least one tightly spaced gap structure is less than 120 nm wide and is not filled with the gap fill nitride.

The at least one tightly spaced gap structure is filled with a MOL dielectric, if it is located in the first semiconductor area, or it is filled with a second MOL dielectric, if it is located in the second semiconductor area.

The width of the gap may be narrower than 120 nm, such as less than 90 nm, or less than 60 nm, or even less than 30 nm.

The semiconductor structure may further comprise a portion of shallow trench isolation located underneath the gap fill nitride. Also, the semiconductor structure may further comprise a gate line located underneath the gap fill nitride.

Preferably, one of the first stress liner and the second stress liner applies a compressive stress to structures therebeneath and the other of the first stress liner and the second stress liner applies a tensile stress to structures therebeneath.

The semiconductor structure may further comprise:

a first middle-of-line (MOL) dielectric located directly on the first stress liner; and

a second middle-of-line (MOL) dielectric located directly on the first stress liner.

The first stress liner may comprise first silicon nitride, the second stress liner may comprise second silicon nitride, the first MOL dielectric may comprise first silicon oxide, and the second MOL dielectric may comprise second silicon oxide.

According to a first embodiment of the present invention, a first top surface of the first MOL dielectric is located above the first stress liner and a second top surface of the second MOL dielectric is located above the second stress liner.

According to a second embodiment of the present invention, the semiconductor structure further comprises an etch stop layer located directly on portions of the first MOL dielectric and directly on portions of the first stress liner. The etch stop layer is a silicon oxide layer.

According to the first embodiment of the present invention, a method of manufacturing a semiconductor structure comprises:

providing a semiconductor substrate;

forming at least one first type MOSFET in a first semiconductor area and at least one second type MOSFET in a second semiconductor area on the semiconductor substrate;

forming a first stack of a first stress liner and a first MOL dielectric directly on the at least one first type MOSFET in the first semiconductor area;

forming a second stack of a second stress liner and a second MOL dielectric directly on the at least one second type MOSFET in the second semiconductor area;

forming an underlapping region between the first semiconductor area and the second semiconductor area, wherein the underlapping region contains neither the first liner nor the second liner; and

forming a gap fill nitride in the underlapping region.

Preferably, a first top surface of the first MOL dielectric is formed above the first stress liner and a second top surface of the second MOL dielectric is formed above the second stress liner.

The method according to the first embodiment may further comprise:

forming the first stress liner directly on the at least one first type MOSFET and directly on the at least one second type MOSFET; and

forming the second stress liner directly on the first MOL dielectric and directly on the at least one second type MOSFET.

The at least one first type MOSFET is covered with the first MOL dielectric after planarization of the first MOL dielectric.

Preferably, the second MOL dielectric is planarized using a portion of the second stress liner in the first semiconductor area as a stopping layer. After planarization of the second MOL dielectric, the second stress liner is removed from the first semiconductor area.

The first stress liner may comprise first silicon nitride, the second stress liner may comprise second silicon nitride, the first MOL dielectric may comprise first silicon oxide, and the second MOL dielectric may comprise second silicon oxide.

According to the second embodiment of the present invention, a method of manufacturing a semiconductor structure comprises:

providing a semiconductor substrate;

forming at least one first type MOSFET in a first semiconductor area and at least one second type MOSFET in a second semiconductor area on the semiconductor substrate;

forming a first stack of a first stress liner and a first MOL dielectric directly on the at least one first type MOSFET in the first semiconductor area;

forming an etch stop layer directly on a portion of the first stress liner;

forming a second stack of a second stress liner and a second MOL dielectric directly on the at least one second type MOSFET in the second semiconductor area;

forming an underlapping region between the first semiconductor area and the second semiconductor area, wherein the underlapping region contains neither the first liner nor the second liner; and

forming a gap fill nitride in the underlapping region.

Preferably, a second top surface of the second MOL dielectric is formed above the second stress liner.

The method according to the second embodiment may further comprise:

forming the first stress liner directly on the at least one first type MOSFET and directly on the at least one second type MOSFET; and

forming the second stress liner directly on the etch stop layer and directly on the at least one second type MOSFET.

Preferably, the first MOL dielectric is planarized using a portion of the first stress liner in the first semiconductor area as a stopping layer.

Also preferably, the second MOL dielectric is planarized using a portion of the second stress liner in the first semiconductor area as a stopping layer. After planarization of the second MOL dielectric, the second stress liner is removed from the first semiconductor area.

The first stress liner may comprise first silicon nitride, the second stress liner may comprise second silicon nitride, the first MOL dielectric may comprise first silicon oxide, and the second MOL dielectric may comprise second silicon oxide.

### BRIEF DESCRIPTION OF THE DRAWINGS

FIGS. 1A-3A and 1B-3B are sequential schematic cross-sectional views of a first prior art structure with overlapping dual stress liners.

FIGS. 4A-8A and 4B-8B are sequential schematic cross-sectional views of a second prior art structure with underlapping dual stress liners and with a gap fill.

FIGS. 9A-18A and 9B-18B are sequential schematic cross-sectional views of an exemplary semiconductor structure with underlapping dual stress liners and with a gap fill according to the first embodiment of the present invention.

FIGS. 19A-27A and 19B-27B are sequential schematic cross-sectional views of an exemplary semiconductor structure with underlapping dual stress liners and with a gap fill according to the second embodiment of the present invention.

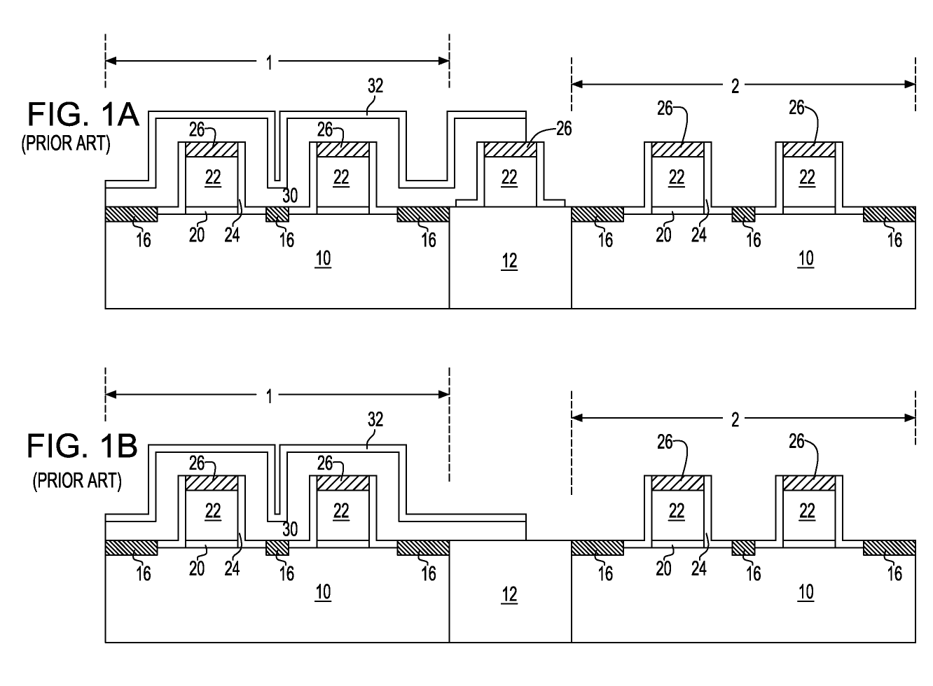

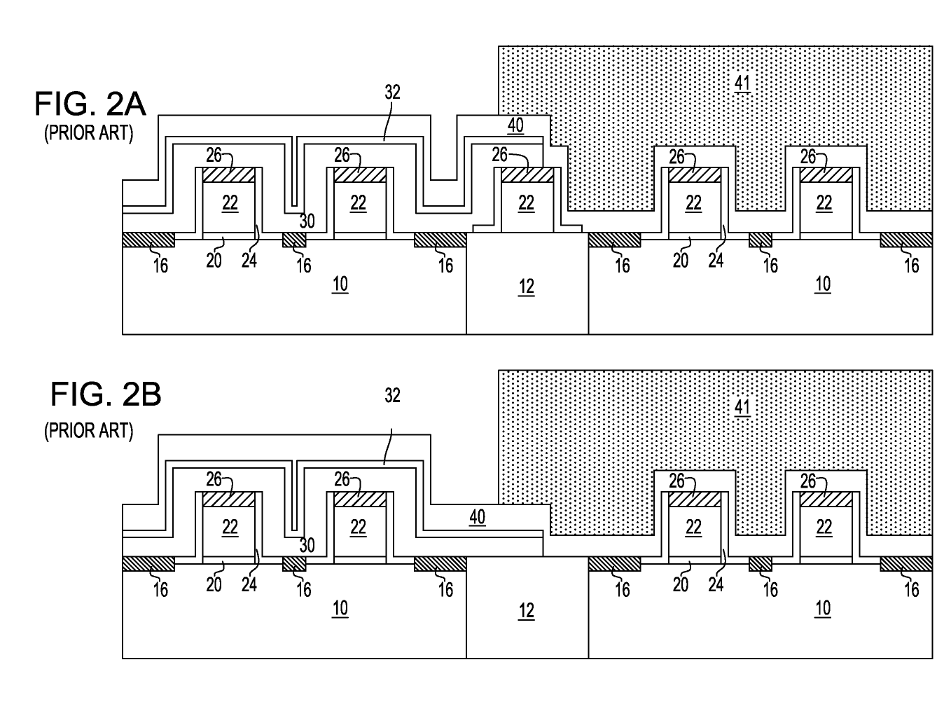

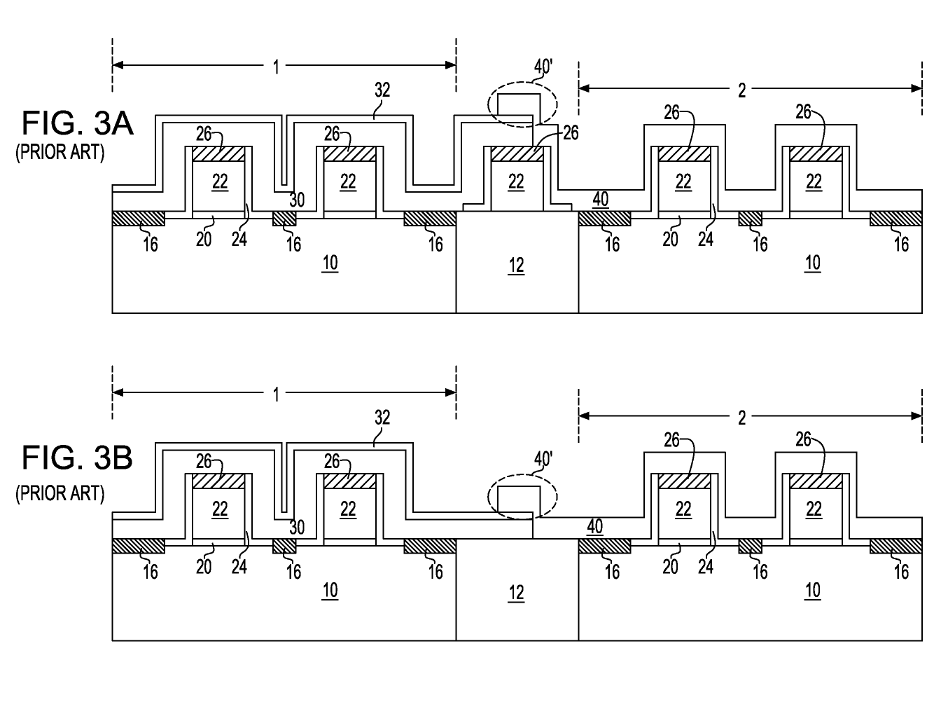

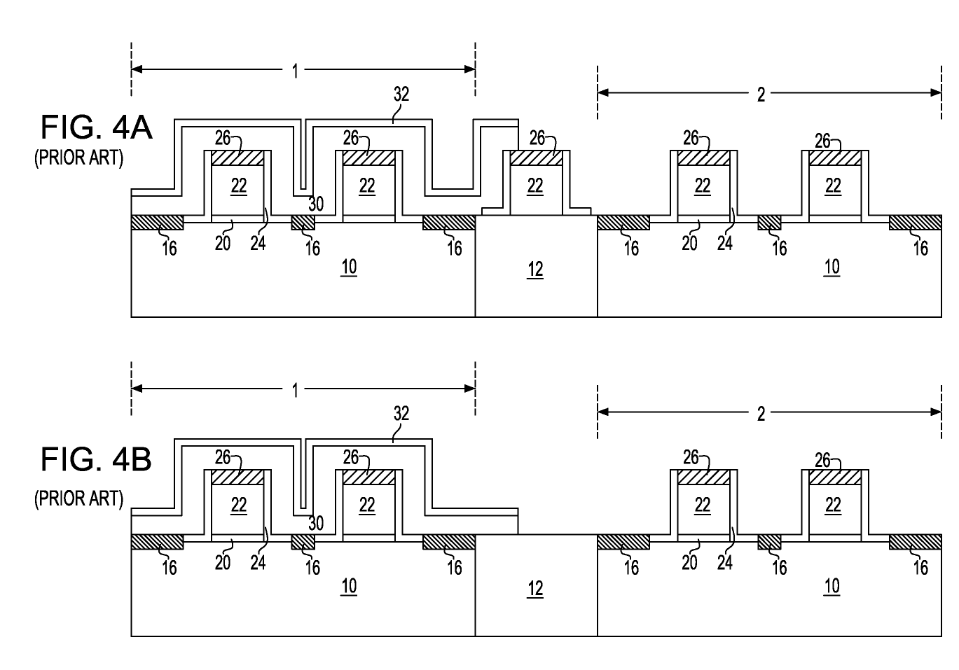

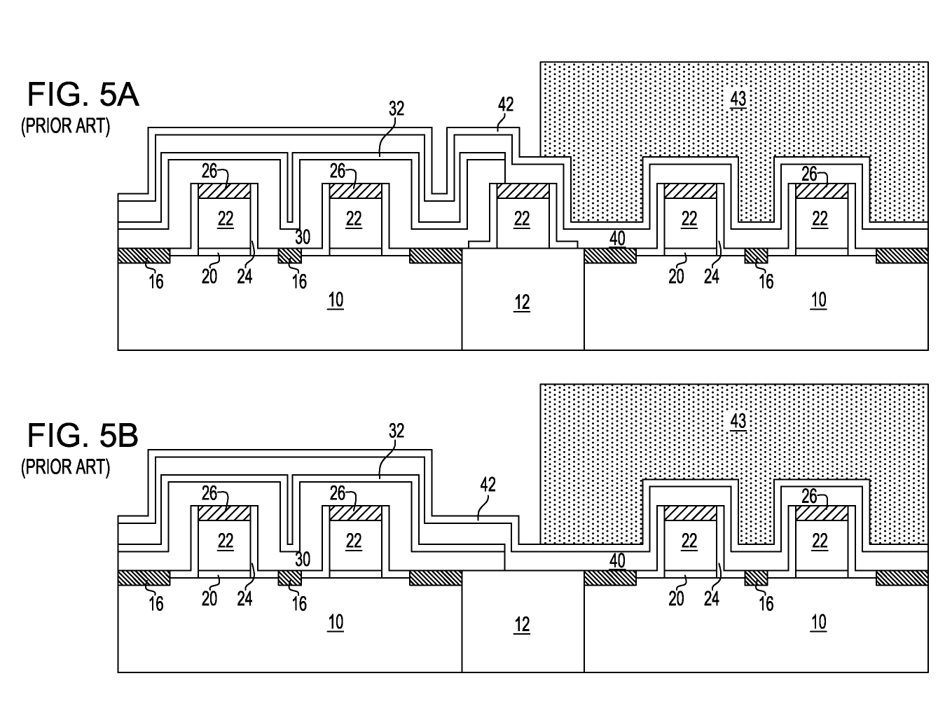

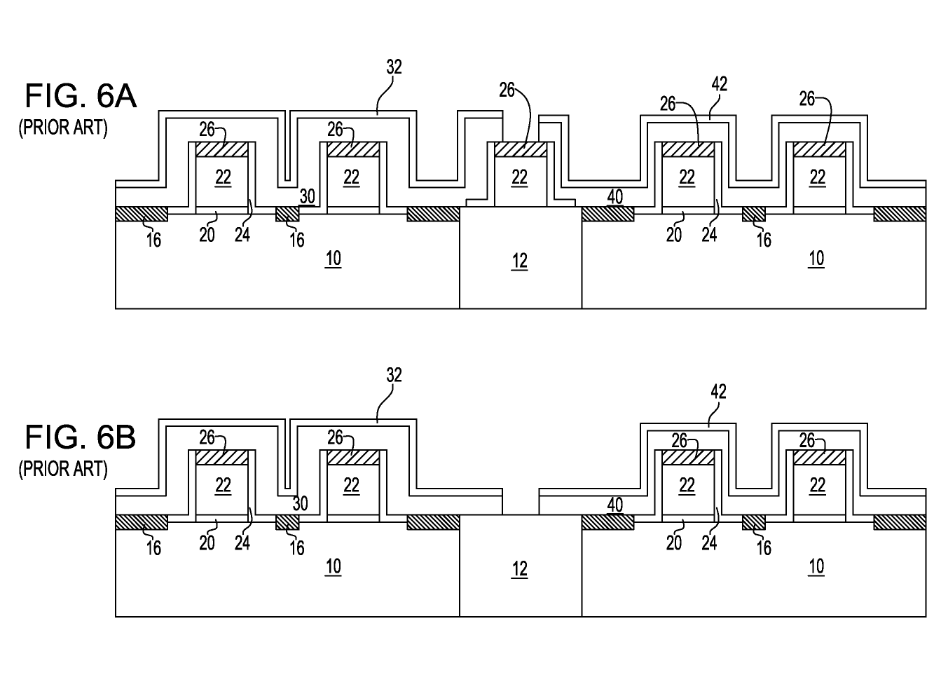

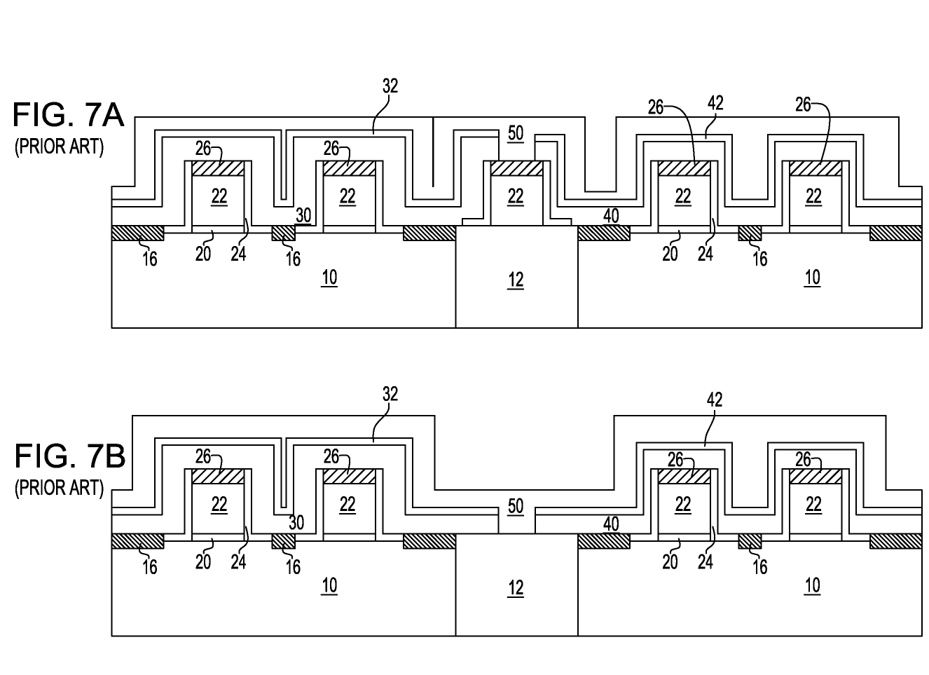

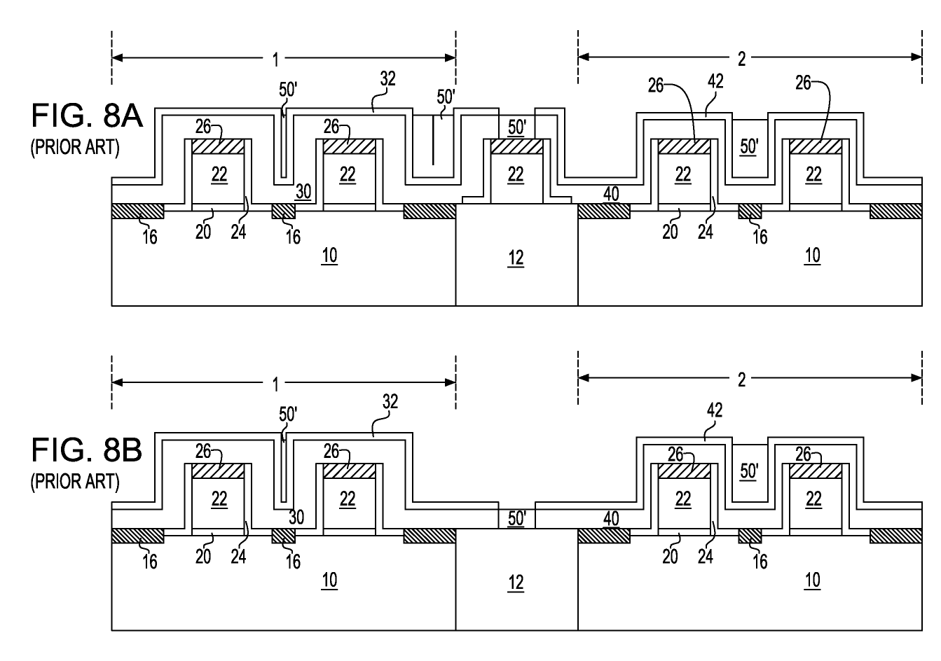

### DETAILED DESCRIPTION OF THE INVENTION

As stated above, the present invention relates to semiconductor structures with a gap fill nitride in underlapping regions between a first semiconductor area and a second semiconductor area that does not plug tightly spaced structures in the first and second semiconductor areas with the gap fill nitride and methods of manufacturing the same. The present invention is now described in detail with accompanying figures.

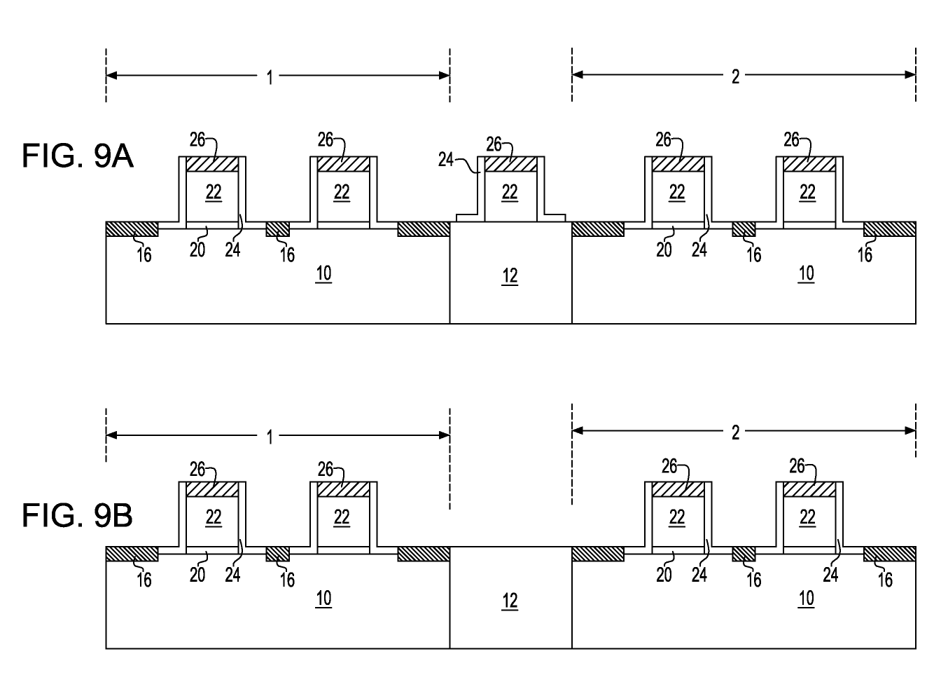

Sequential vertical cross-sections of an exemplary semiconductor structure according to a first embodiment of the present invention are shown in FIGS. 9A-18A and 9B-18B. Figures identified with a suffix “A” are vertical cross-sections of the exemplary semiconductor structure according to the first embodiment at a location with a gate conductor 22 over shallow trench isolation 12. Figures identified with a suffix “B” are vertical cross-sections of the exemplary semiconductor structure according to the first embodiment at a location without a gate conductor 22 over shallow trench isolation 12. Figures with the same figure numeral refer to the same stage of manufacture.

Referring to FIGS. 9A and 9B, an initial semiconductor structure according to the first embodiment of the present invention comprises a first semiconductor area 1 and a second semiconductor area 2, each of which comprises a portion of a semiconductor substrate 10, a gate dielectric 20, patterned gate conductors 22, gate spacers 24, gate silicide 26, and source and drain silicide 16. A gate line comprising a gate conductor 22, gate spacers 24, and gate silicide 26 is also shown in FIG. 9A over shallow trench isolation 12. The first semiconductor area 1 comprises at least one first type MOSFET and the second semiconductor area 2 comprises at least one second type MOSFET. The at least one first type MOSFET may comprise at least one p-type MOSFET and the at least one second type MOSFET may comprise at least one n-type MOSFET. Alternatively, the at least one first type MOSFET may comprise at least one n-type MOSFET and the at least one second type MOSFET may comprise at least one p-type MOSFET. If multiple MOSFETs are present in each of the first and second semiconductor areas (1, 2), all of the first type MOSFETs are preferably of the one type, i.e., p-type or n-type, and all of the second type MOSFETs are of the other type, i.e., n-type or p-type.

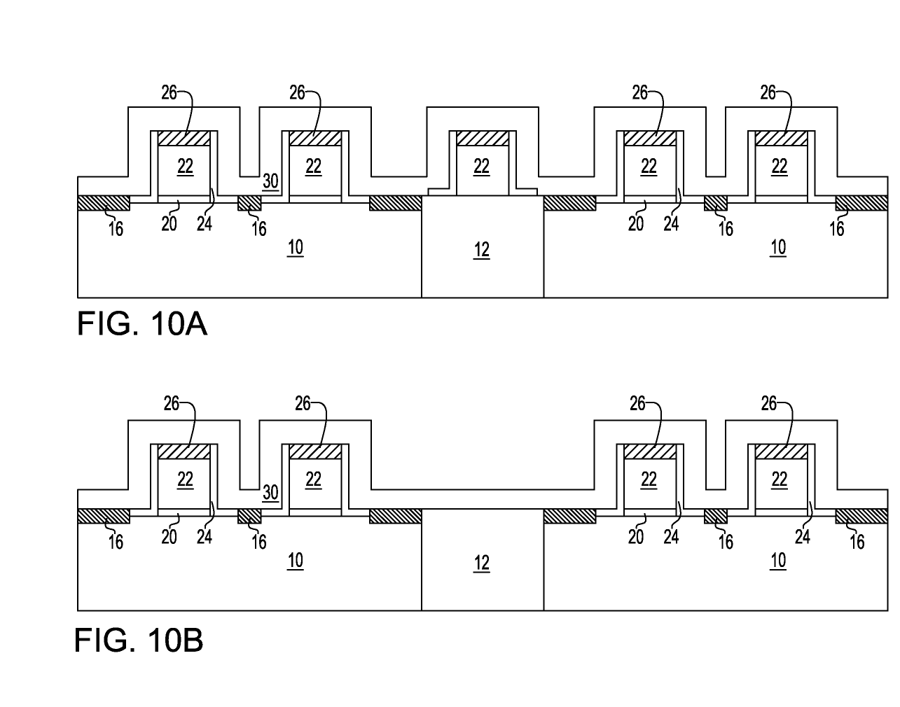

Referring to FIGS. 10A and 10B, a first stress liner 30 is deposited over the first semiconductor area 1, the second semiconductor area 2, and the shallow trench isolation 12 between the two semiconductor areas (1, 2). Preferably, the first stress liner 30 applies a first stress to the at least one first type MOSFET in the first semiconductor area 1. More preferably, the stress applied by the first stress liner 30 to the structures below, and especially to the channel of the at least one first type MOSFET enhances minority carrier mobility in the channel of the at least one first type MOSFET in the first semiconductor area 1. The first stress liner 30 preferably comprises first silicon nitride. The first stress liner 30 may be deposited by chemical vapor deposition (CVD), and preferably by plasma enhanced chemical vapor deposition (PECVD). The thickness of the first stress liner 30 is in the range from about 10 nm to about 120 nm, and more preferably from about 30 nm to about 90 nm.

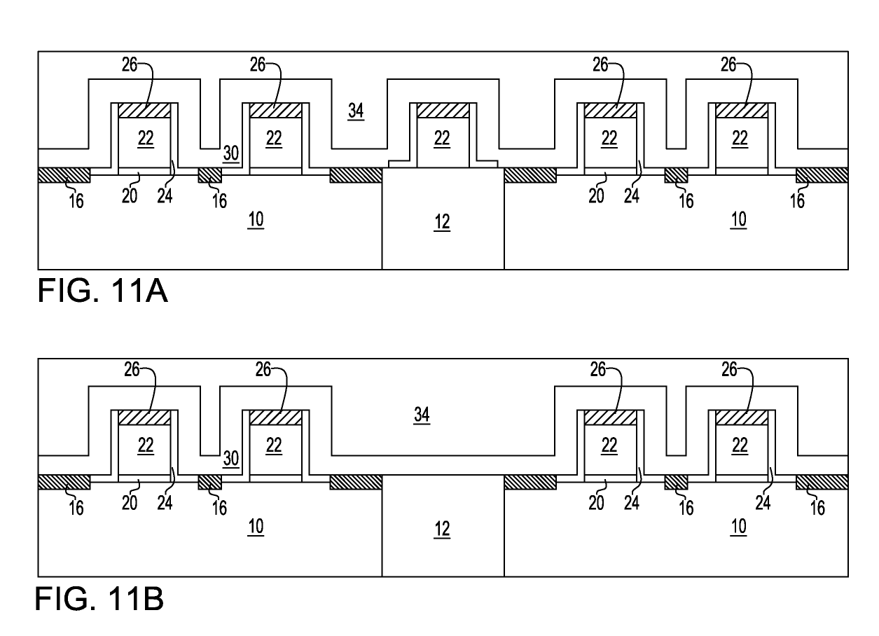

Referring to FIGS. 11A and 11B, a first middle-of-line (MOL) dielectric 34 is deposited over the entire semiconductor structure and is subsequently planarized by chemical mechanical planarization (CMP) according to the first embodiment of the present invention. The first MOL dielectric 34 is preferably a silicon oxide, such as undoped silicate glass (USG), borophosphosilicate glass (BPSG), or a fluorosilicate glass (FSG). The first MOL dielectric 34 is deposited by chemical vapor deposition (CVD), and preferably by sub-atmospheric chemical vapor deposition (SACVD), plasma enhanced chemical vapor deposition (PECVD), or high density plasma chemical vapor deposition (HDPCVD). As deposited, the thickness of the first MOL dielectric over the highest portion 31 of the first stress liner 30 is in the range from about 100 nm to about 600 nm, and preferably from about 200 nm to about 400 nm. Preferably, the CMP process stops before the first stress liner 30 is exposed, and therefore, the first liner 30 is still covered with the first MOL dielectric 34 after planarization of the first MOL dielectric 34. The thickness of the remaining first MOL dielectric 34 over the highest portion 31 is in the range from about 10 nm to about 300 and is preferably in the range from about 10 nm to about 150 nm.

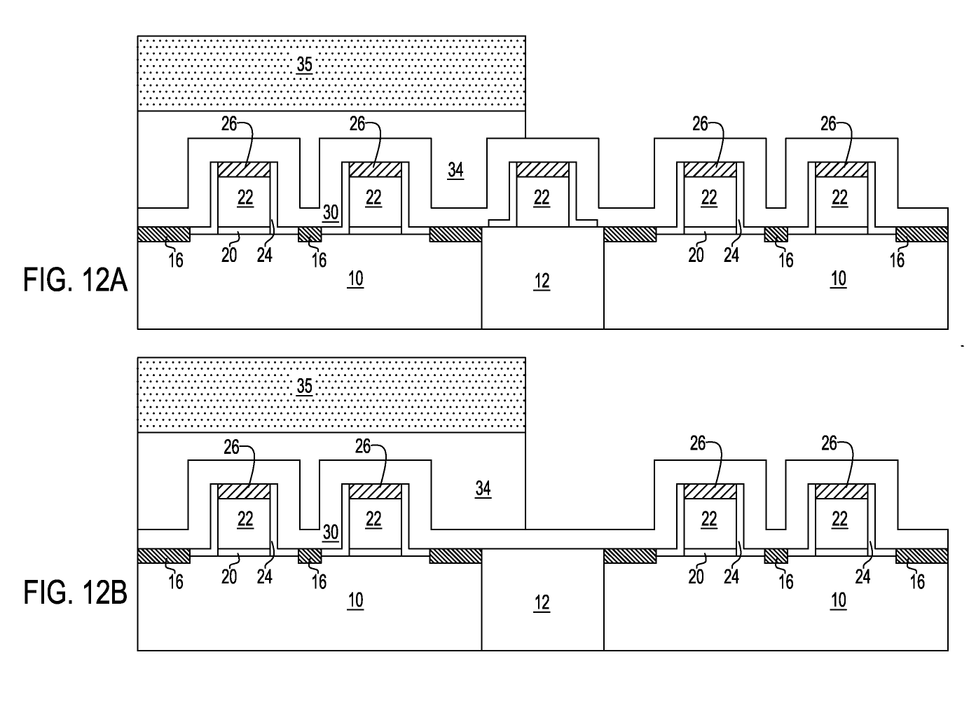

Referring to FIGS. 12A and 12B, a first photoresist 35 is applied over the surface of the planarized first MOL dielectric 34 and is lithographically patterned such that the first semiconductor area 1 and a portion of the boundary area between the first semiconductor area 1 and the second semiconductor area 2 are covered with the patterned first photoresist 35. The portion of the gate line over the shallow trench isolation 12 that is not covered with the first photoresist 35 in FIG. 12A is at least as wide as the overlay tolerance of a block mask to be subsequently used for patterning a second stress liner. The exposed portion of the first MOL dielectric 34 is etched preferably by a first reactive ion etch (RIE). The first RIE preferably stops on the first stress liner 30.

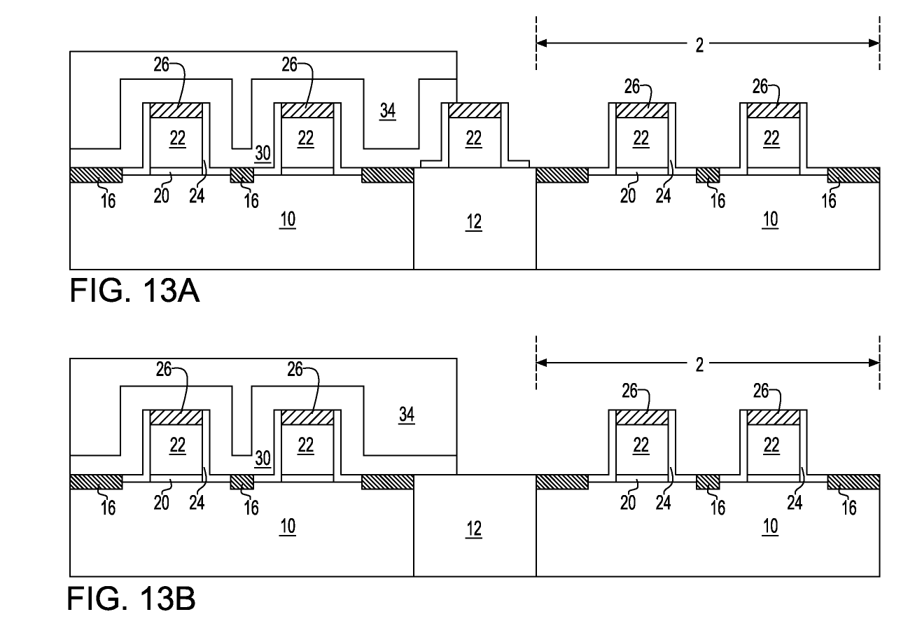

Referring to FIGS. 13A and 13B, the patterned first photoresist 35 is removed and the first MOL dielectric 34 is used as a hardmask for a subsequent second reactive ion etch of the first stress liner 30. The first stress liner 30 is etched from portions of the semiconductor substrate that is not covered with the first MOL dielectric 34, including the second semiconductor area 2. The second etch preferably stops on the gate spacers 24, the gate silicide 26, and the source and drain silicide 16. A suitable surface cleaning may be performed to remove RIE residues. At this point, formation of a first stack of the first stress liner 30 and the first MOL dielectric in the first semiconductor area 1 is complete.

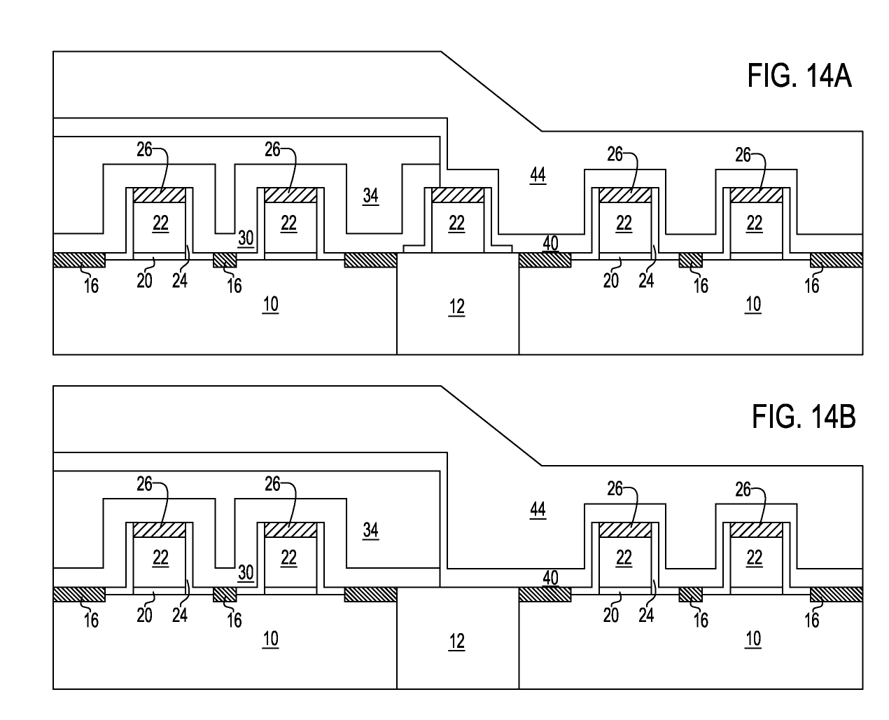

Referring to FIGS. 14A and 14B, a second stress liner 40 and a second middle-of-line (MOL) dielectric 44 are deposited directly on the first stack and directly on the at least one second type MOSFET in the second semiconductor area 2. Preferably, the second stress liner 40 applies a second stress to the at least one second type MOSFET in the second semiconductor area 2. More preferably, the stress applied by the second stress liner 40 to the structures below, and especially to the channel of the at least one second type MOSFET enhances minority carrier mobility in the channel of the at least one second type MOSFET in the second semiconductor area 2. The second stress liner 40 preferably comprises a second silicon nitride. The second stress liner 40 may be deposited by chemical vapor deposition (CVD), and preferably by plasma enhanced chemical vapor deposition (PECVD). The thickness of the second stress liner 40 is in the range from about 10 nm to about 120 nm, and more preferably from about 30 nm to about 90 nm.

The second MOL dielectric 44 is preferably a silicon oxide, such as undoped silicate glass (USG), borophosphosilicate glass (BPSG), or a fluorosilicate glass (FSG). The second MOL dielectric 44 is deposited by chemical vapor deposition (CVD), and preferably by sub-atmospheric chemical vapor deposition (SACVD), plasma enhanced chemical vapor deposition (PECVD), or high density plasma chemical vapor deposition (HDPCVD). As deposited, the thickness of the second MOL dielectric in the first semiconductor area 1 is in the range from about 100 nm to about 600 nm, and preferably from about 200 nm to about 400 nm.

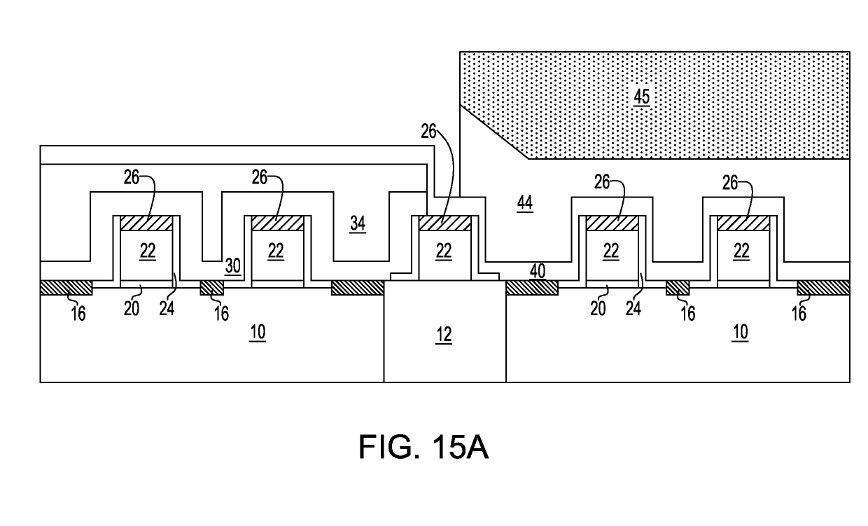

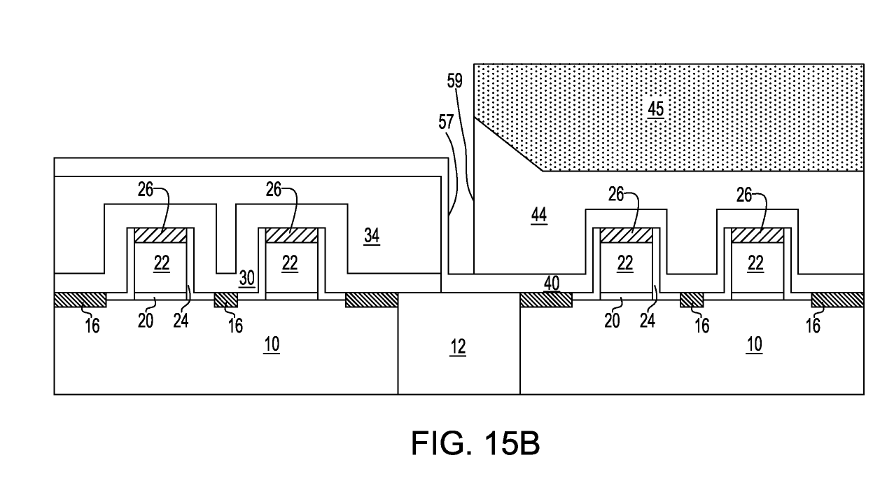

Referring to FIGS. 15A and 15B, a second photoresist 45 is applied over the surface of the second MOL dielectric 44 and is lithographically patterned such that the second semiconductor area 2 and a portion of the boundary area between the first semiconductor area 1 and the second semiconductor area 2 are covered with the patterned second photoresist 45. There is an underlap between the edge of the second photoresist 45 and the substantially vertical outer wall 57 of a portion of the second stress liner 40 that is located directly on the first stack of the first stress liner 30 and the first MOL dielectric 34. The exposed portion of the second MOL dielectric 44 is etched preferably by a third reactive ion etch (RIE). The third RIE preferably stops on the second stress liner 40. At the end of the third RIE, a gap is formed between the substantially vertical outer wall 57 of the portion of the second stress liner 40 and the newly formed second MOL dielectric wall 59 of the second MOL dielectric 44.

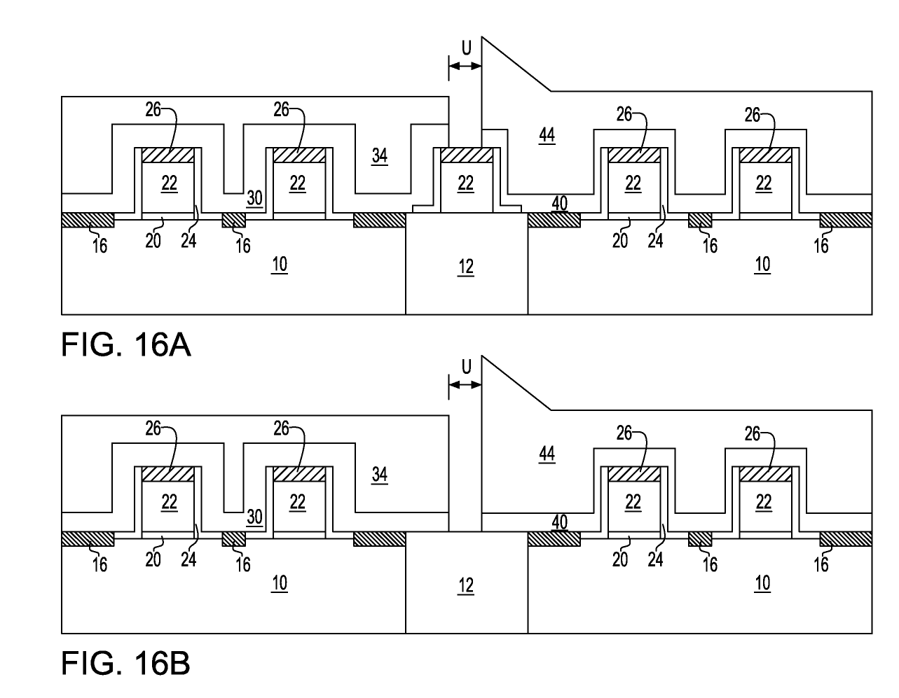

Referring to FIGS. 16A and 16B, the second photoresist 45 is removed and the exposed portion of the second stress liner 44 is etched. A wet etch process may be employed to etch the second stress liner 44 selective to the second MOL dielectric 44 and the first MOL dielectric 34. Alternatively, a fourth reactive ion etch (RIE) may be employed utilizing the second MOL dielectric 44 as a hardmask. Preferably, the fourth RIE etches the second stress liner 40 selective to the second MOL dielectric 44 and selective to the first MOL dielectric 34. The etch of the exposed portion of the second stress liner 44 forms an underlapping region U between the first stack of the first stress liner 30 and the first MOL dielectric 34 and the second stack of the second stress liner 40 and the second MOL dielectric 44, in which neither the first stack nor the second stack in present. Consequently, there is neither the first stress liner 30 nor the second stress liner 40 within the underlapping region U.

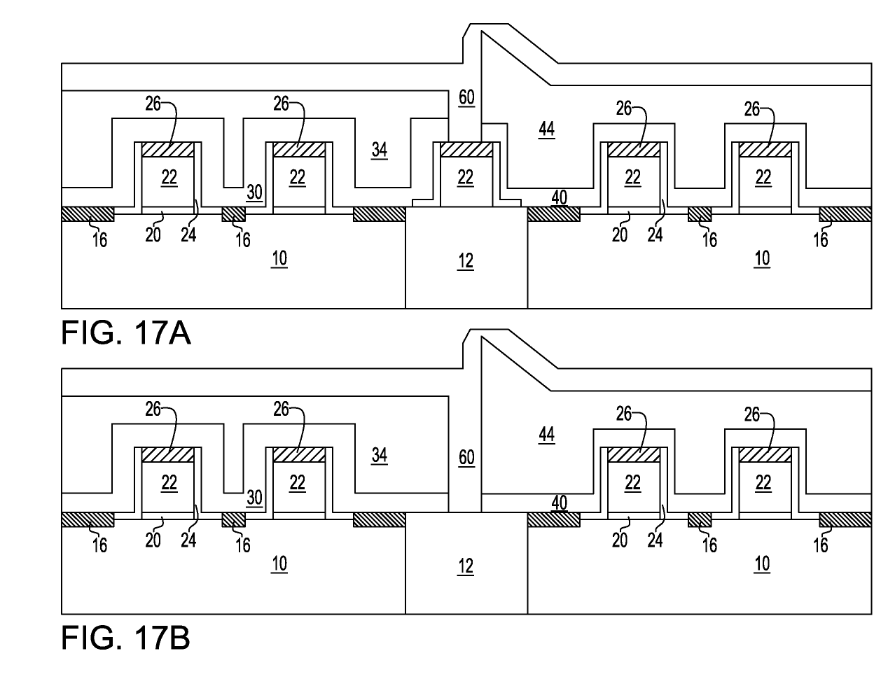

Referring to FIGS. 17A and 17B, a gap fill nitride layer 60 is deposited directly on the first stack of the first stress liner 30 and the first MOL dielectric 34, directly on the second stack of the second stress liner 40 and the second MOL dielectric 44, and in the underlapping region U. Preferably, the gap fill nitride layer 60 applies no stress or low stress to the semiconductor structure below. For example, the stress applied to the structure below by the gap fill nitride layer 60 may be at least one order of magnitude lower than the stress applied to the structures below either by the first stress liner 30 or by the second stress liner 40. The gap fill nitride layer 60 may be deposited by chemical vapor deposition (CVD), and preferably by plasma enhanced chemical vapor deposition (PECVD). The thickness of the gap fill nitride layer 60 is in the range from about 10 nm to about 120 nm, and more preferably from about 30 nm to about 90 nm, and is most preferably around 60 nm.

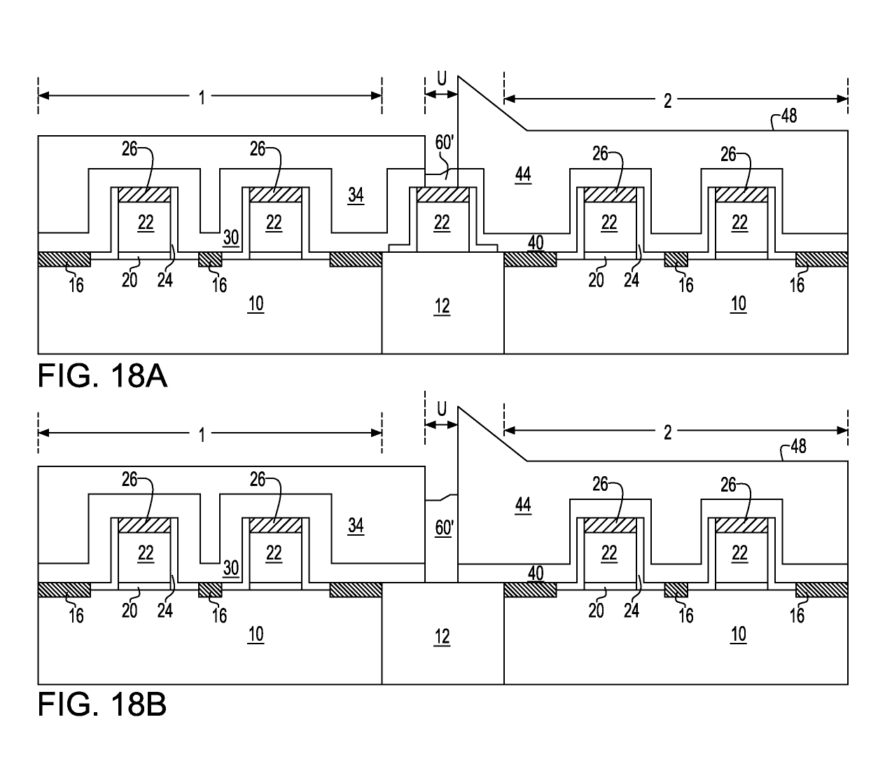

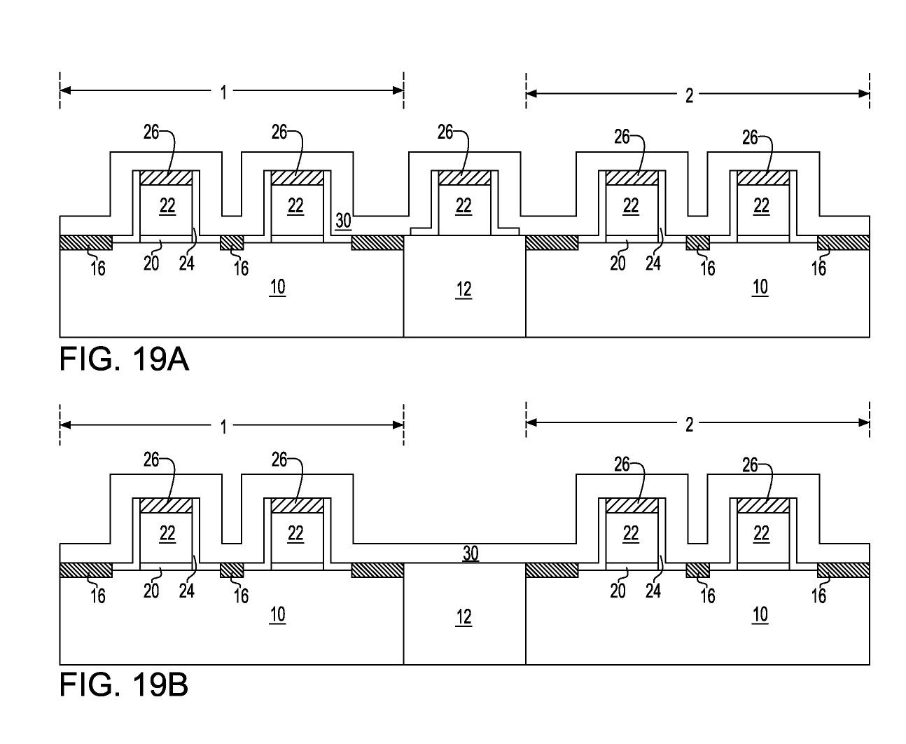

Referring to FIGS. 18A and 18B, the gap fill nitride layer 60 is etched back and removed completely from above the first MOL dielectric layer 34 and from above the second MOL dielectric layer 44. A remaining gap fill nitride 60′ is formed in the underlapping region U. The height of the remaining gap fill nitride 60′ may vary depending on whether a gate line is present in the underlapping region U, as shown in FIG. 18A, or not, as shown in FIG. 18B. The etch of the gap fill nitride layer 60 may be endpointed on a sharp drop in the amount of detected nitride etch residue for accurate process control since the amount of nitride etch residue in the etch chamber decreases sharply once the gap fill nitride layer 60 is removed from the top of the first MOL dielectric 34 and from the top of the second MOL dielectric 44. The overetch after the detection of the endpoint may be timed for accurate control of the depth of recess of the remaining gap fill nitride 60′ from the top of the first MOL dielectric layer 30.

Sequential vertical cross-sections of an exemplary semiconductor structure according to a second embodiment of the present invention are shown in FIGS. 19A-27A and 19B-27B. Figures identified with a suffix “A” are vertical cross-sections of the exemplary semiconductor structure according to the second embodiment at a location with a gate conductor 22 over shallow trench isolation 12. Figures identified with a suffix “B” are vertical cross-sections of the exemplary semiconductor structure according to the second embodiment at a location without a gate conductor 22 over shallow trench isolation 12. Figures with the same figure numeral refer to the same stage of manufacture.

Referring to FIGS. 19A and 19B, an initial semiconductor structure according to the second embodiment of the present invention comprises a first semiconductor area 1 and a second semiconductor area 2, both of which comprise a semiconductor substrate 10, a gate dielectric 20, patterned gate conductors 22, gate spacers 24, gate silicide 26, and source and drain silicide 16. A gate line comprising a gate conductor 22, gate spacers 24, and gate silicide 26 is also shown in FIG. 9A over shallow trench isolation 12. The first semiconductor area 1 comprises at least one first type MOSFET and the second semiconductor area 2 comprises at least one second type MOSFET. The at least one first type MOSFET may comprise at least one p-type MOSFET and the at least one second type MOSFET may comprise at least one n-type MOSFET. Alternatively, the at least one first type MOSFET may comprise at least one n-type MOSFET and the at least one second type MOSFET may comprise at least one p-type MOSFET. If multiple MOSFETs are present in each of the first and second semiconductor areas (1, 2), all of the first type MOSFETs are preferably of the one type, i.e., p-type or n-type, and all of the second type MOSFETs are of the other type, i.e., n-type or p-type.

FIGS. 19A and 19B also shows a first stress liner 30 that is also formed over the first semiconductor area 1, the second semiconductor area 2, and the shallow trench isolation 12 between the two semiconductor areas (1, 2). Preferably, the first stress liner 30 applies a first stress to the at least one first type MOSFET in the first semiconductor area 1. More preferably, the stress applied by the first stress liner 30 to the structures below, and especially to the channel of the at least one first type MOSFET enhances minority carrier mobility in the channel of the at least one first type MOSFET in the first semiconductor area 1. The first stress liner 30 preferably comprises first silicon nitride. The first stress liner 30 may be deposited by chemical vapor deposition (CVD), and preferably by plasma enhanced chemical vapor deposition (PECVD). The thickness of the first stress liner 30 is in the range from about 10 nm to about 120 nm, and more preferably from about 30 nm to about 90 nm.

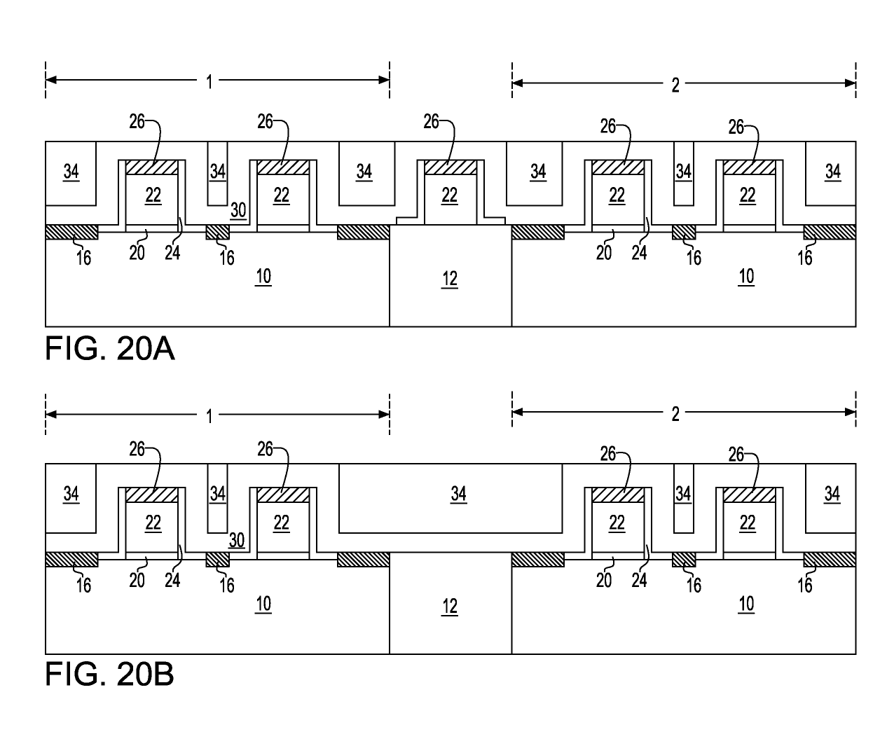

Referring to FIGS. 20A and 20B, a first middle-of-line (MOL) dielectric 34 is deposited over the entire semiconductor structure and is subsequently planarized by chemical mechanical planarization (CMP) according to the second embodiment of the present invention. The CMP process stops on the first stress liner 30, i.e., the first MOL dielectric 34 is planarized using the top surface of the portions of the first stress liner 30 located over the gate lines. In both the first semiconductor area 1 and the second semiconductor area 2, the portions of the first stress liner located above gate lines. Preferably, The first MOL dielectric 34 is preferably a silicon oxide, such as undoped silicate glass (USG), borophosphosilicate glass (BPSG), or a fluorosilicate glass (FSG). The first MOL dielectric 34 is deposited by chemical vapor deposition (CVD), and preferably by sub-atmospheric chemical vapor deposition (SACVD), plasma enhanced chemical vapor deposition (PECVD), or high density plasma chemical vapor deposition (HDPCVD). As deposited, the thickness of the first MOL dielectric measured from above the gate lines is in the range from about 100 nm to about 600 nm, and preferably from about 200 nm to about 400 nm. At this point, the top surface of the first stress liner 30 over gate lines is coplanar with the top surface of the planarized first MOL dielectric layer 34.

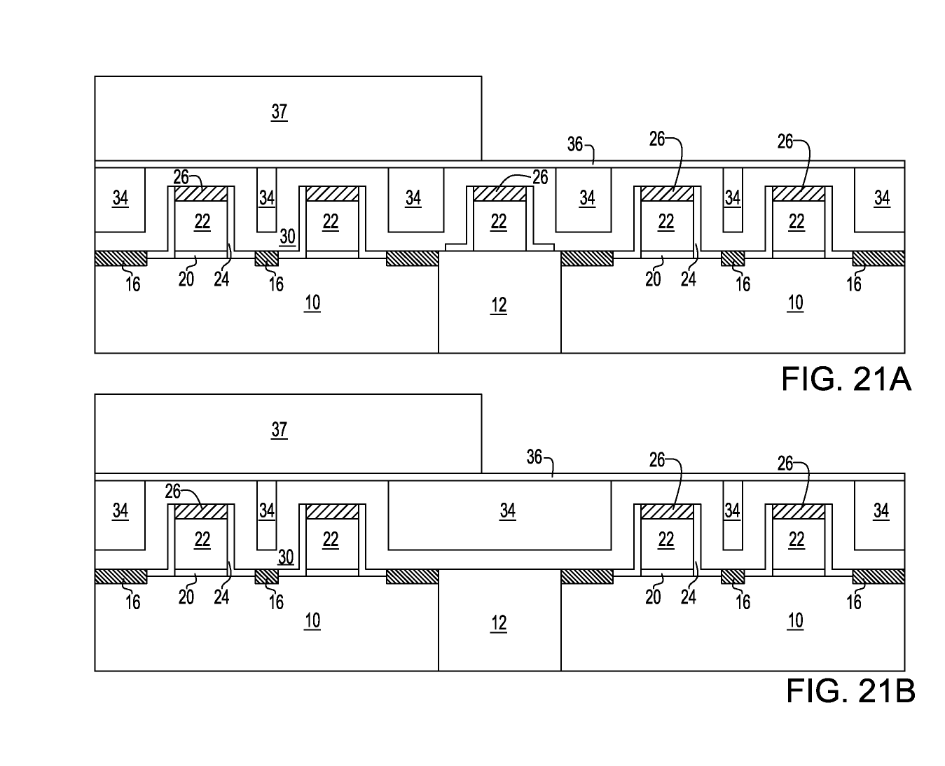

Referring to FIGS. 21A and 21B, an etch stop layer 36 is formed on top of the planarized first MOL dielectric layer 34. The etch stop layer 36 directly contacts portions of the first stress liner 30 and the top surfaces of the planarized first MOL dielectric 34. The etch stop layer 36 is preferably a silicon oxide layer, and more preferably a low temperature oxide (LTO) layer. The etch stop layer 36 may be deposited by chemical vapor deposition (CVD), and preferably by plasma enhanced chemical vapor deposition (PECVD). The thickness of the etch stop layer 36 is in the range from about 5 nm to about 30 nm, and more preferably from about 10 nm to about 20 nm.

A first photoresist 37 is applied over the surface of the etch stop layer 36 and is lithographically patterned such that the first semiconductor area 1 and a portion of the boundary area between the first semiconductor area 1 and the second semiconductor area 2 are covered with the patterned first photoresist 37. The portion of the gate line over the shallow trench isolation 12 that is not covered with the first photoresist 37 in FIG. 21A is at least as wide as the overlay tolerance of a block mask to be subsequently used for patterning a second stress liner. The exposed portion of the etch stop layer 36 is etched either by a wet etch or by a first reactive ion etch (RIE). If a wet etch is employed, the wet etch is preferably selective to the underlying first stress liner 30 and the first MOL dielectric 34. If a first RIE is employed, the first RIE preferably stops on the first stress liner 30.

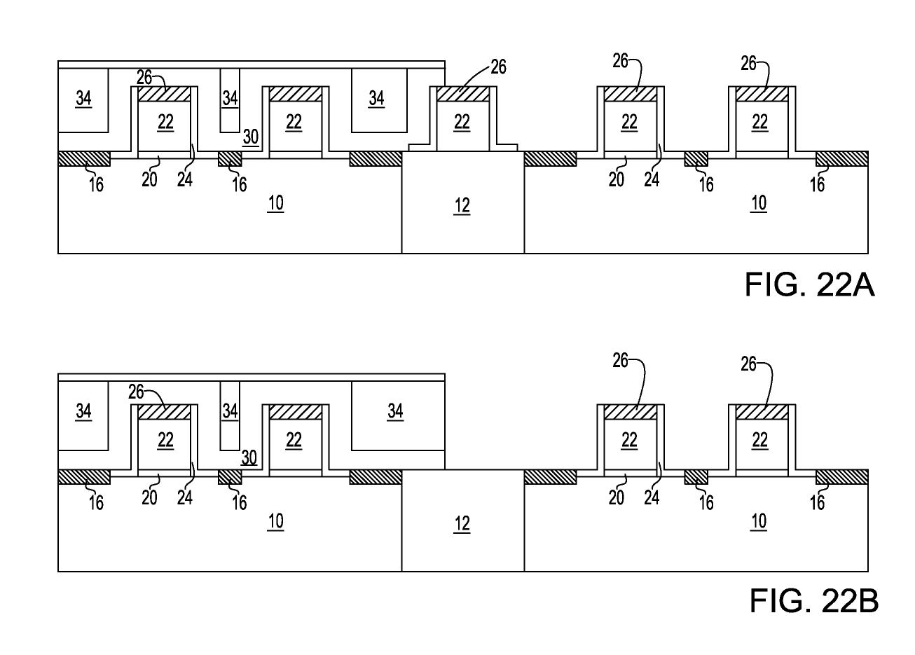

Referring to FIGS. 22A and 22B, the patterned first photoresist 37 is removed and the etch stop layer 36 is used as a hardmask for a subsequent second reactive ion etch of the first stress liner 30 and the first MOL dielectric 34. The first stress liner 30 and the first MOL dielectric 34 are etched from portions of the semiconductor substrate that is not covered with the etch stop layer 36, including the second semiconductor area 2. The second etch preferably stops on the gate spacers 24, the gate silicide 26, and the source and drain silicide 16. A suitable surface cleaning may be performed to remove RIE residues. At this point, formation of the etch stop layer 36 and a first stack of the first stress liner 30 and the first MOL dielectric in the first semiconductor area 1 is complete.

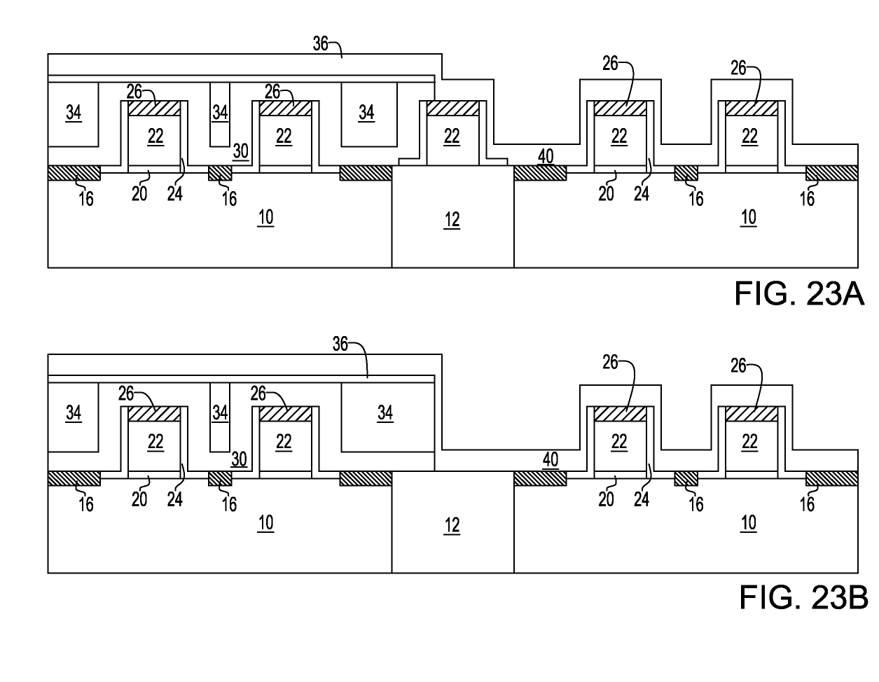

Referring to FIGS. 23A and 23B, a second stress liner 40 is deposited directly on the etch stop layer 36 and directly on the at least one second type MOSFET in the second semiconductor area 2. Preferably, the second stress liner 40 applies a second stress to the at least one second type MOSFET in the second semiconductor area 2. More preferably, the stress applied by the second stress liner 40 to the structures below, and especially to the channel of the at least one second type MOSFET enhances minority carrier mobility in the channel of the at least one second type MOSFET in the second semiconductor area 2. The second stress liner 40 preferably comprises second silicon nitride. The second stress liner 40 may be deposited by chemical vapor deposition (CVD), and preferably by plasma enhanced chemical vapor deposition (PECVD). The thickness of the second stress liner 40 is in the range from about 10 nm to about 120 nm, and more preferably from about 30 nm to about 90 nm.

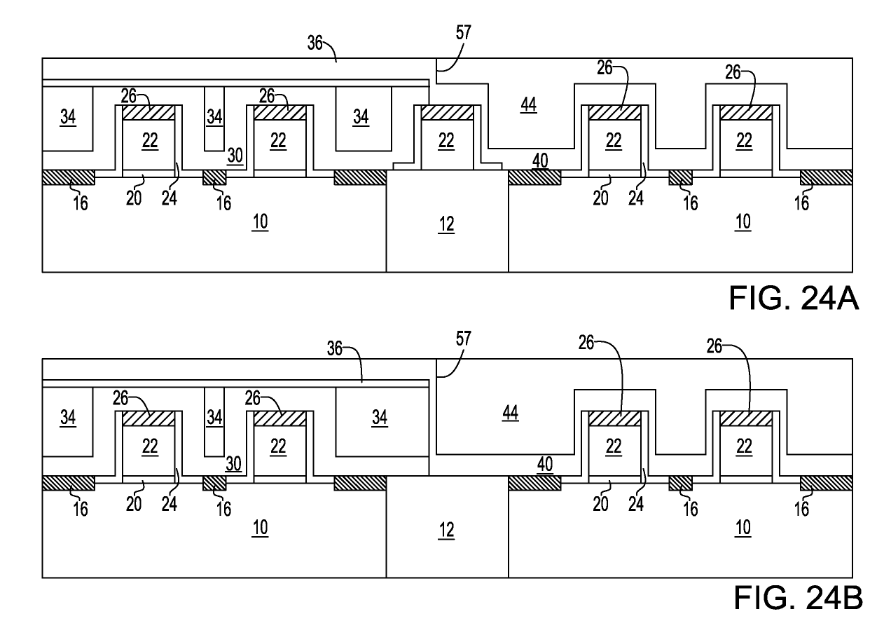

Referring to FIGS. 24A and 24B, a second middle-of-line (MOL) dielectric 44 is deposited directly on the second stress liner 40 and is planarized utilizing the portion of the second stress liner 40 over the first semiconductor area 1 as a stopping layer. The second MOL dielectric 44 is preferably a silicon oxide, such as undoped silicate glass (USG), borophosphosilicate glass (BPSG), or a fluorosilicate glass (FSG). The second MOL dielectric 44 is deposited by chemical vapor deposition (CVD), and preferably by sub-atmospheric chemical vapor deposition (SACVD), plasma enhanced chemical vapor deposition (PECVD), or high density plasma chemical vapor deposition (HDPCVD). As deposited, the thickness of the second MOL dielectric in the first semiconductor area 1 is in the range from about 100 nm to about 600 nm, and preferably from about 200 nm to about 400 nm. After the planarization, the top of the second MOL dielectric 44 in the second semiconductor area 2 is coplanar with the top surface of the second stress liner 40 in the first semiconductor area 1. A substantially vertical outer wall 57 of a portion of the second stress liner 40 is located directly on the edge of the stack of first MOL dielectric 34 and the etch stop layer 36.

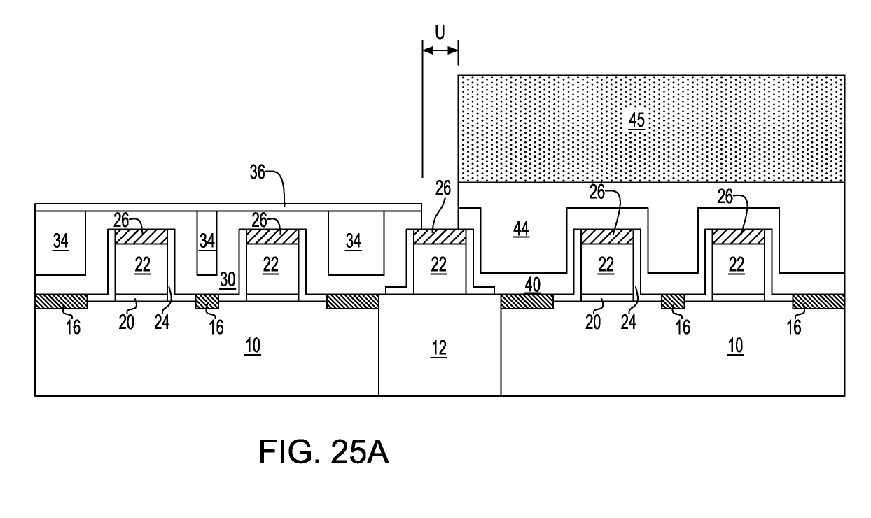

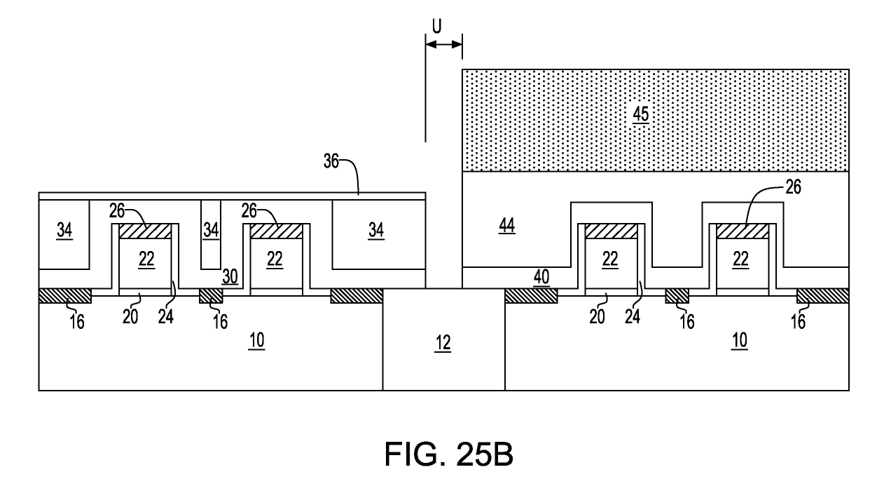

Referring to FIGS. 25A and 25B, a second photoresist 45 is applied over the surface of the second MOL dielectric 44 in the second semiconductor area 2 and over the surface of the second stress liner 40 in the first semiconductor area 1 and is lithographically patterned such that the second semiconductor area 2 and a portion of the boundary area between the first semiconductor area 1 and the second semiconductor area 2 are covered with the patterned second photoresist 45. There is an underlap between the edge of the second photoresist 45 and the substantially vertical outer wall 57 (shown in FIGS. 24A and 24B) of the portion of the second stress liner 40 that is located directly on the edge of the stack of first MOL dielectric 34 and the etch stop layer 36. The exposed portion of the second stress liner 40 is etched preferably by a third reactive ion etch (RIE). The third RIE preferably stops on the gate silicide 26, the gate spacers 24, or on the shallow trench isolation 12. The etch of the exposed portion of the second stress liner 44 forms an underlapping region U between the stack of first MOL dielectric 34 and the etch stop layer 36 and the stack of the second MOL dielectric 44 and the second stress liner 40, in which neither the first stack nor the second stack in present. Consequently, there is neither the first stress liner 30 nor the second stress liner 40 within the underlapping region U.

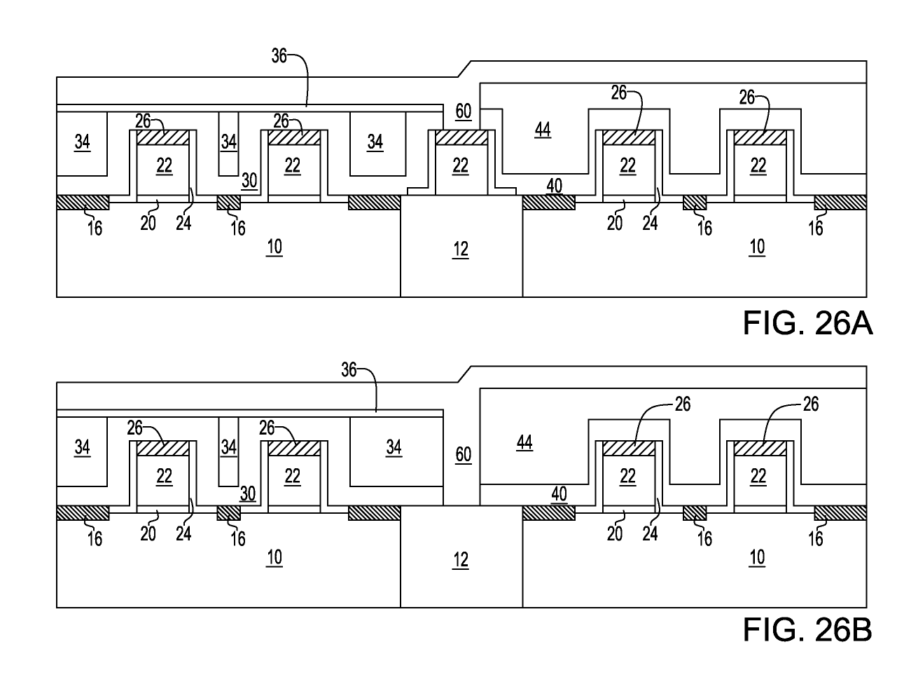

Referring to FIGS. 26A and 26B, the second photoresist 45 is removed and a suitable surface clean such as a wet etch is performed as needed. A gap fill nitride layer 60 is deposited directly on the etch stop layer 36, directly on the second stack of the second stress liner 40 and the second MOL dielectric 44, and in the underlapping region U. Preferably, the gap fill nitride layer 60 applies no stress or low stress to the semiconductor structure below. For example, the stress applied to the structure below by the gap fill nitride layer 60 may be at least one order of magnitude lower than the stress applied to the structures below either by the first stress liner 30 or by the second stress liner 40. The gap fill nitride layer 60 may be deposited by chemical vapor deposition (CVD), and preferably by plasma enhanced chemical vapor deposition (PECVD). The thickness of the gap fill nitride layer 60 is in the range from about 10 nm to about 120 nm, and more preferably from about 30 nm to about 90 nm, and is most preferably around 60 nm.

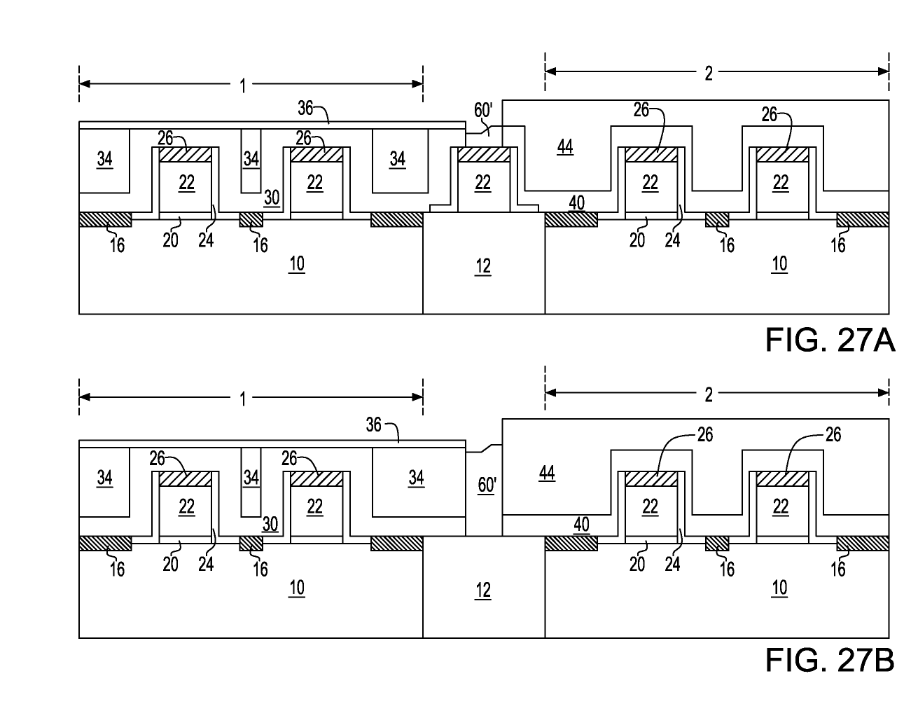

Referring to FIGS. 27A and 27B, the gap fill nitride layer 60 is etched back and removed completely from above the etch stop layer 36 and from above the second MOL dielectric layer 44. A remaining gap fill nitride 60′ is formed in the underlapping region U. The height of the remaining gap fill nitride 60′ may vary depending on whether a gate line is present in the underlapping region U, as shown in FIG. 27A, or not, as shown in FIG. 27B. The etch of the gap fill nitride layer 60 may be endpointed on a sharp drop in the amount of detected nitride etch residue for accurate process control since the amount of nitride etch residue in the etch chamber decreases sharply once the gap fill nitride layer 60 is removed from the top of the etch stop layer 36 and from the top of the second MOL dielectric 44. The overetch after the detection of the endpoint may be timed for accurate control of the depth of recess of the remaining gap fill nitride 60′ from the top of the etch stop layer 36 or from the top of the second MOL dielectric 44.

The resulting structures according to both embodiments of the present invention provide a continuous mobile ion diffusion barrier across the entire surface of a CMOS semiconductor structure. The continuous mobile ion barrier comprises the first stress liner 30, the second stress liner 40, and the remaining gap fill nitride 60′. The resulting structure does not contain any gap fill nitride in the first semiconductor area 1 or in the semiconductor structure 2 even if the first and second semiconductor areas comprise tightly spaced gap structures between two substantially vertical walls of the first stress liner or between two substantially vertical walls of the second stress liner. In other words, the tightly spaced gap structures are not filled with a gap fill nitride.

The aspect of the present invention in which the tightly spaced gap structures are not filled with a gap fill nitride contrasts with the second prior art, according to which tightly spaced gap structures with a width less than twice the thickness of the deposited gap fill nitride is plugged with the gap fill nitride and cannot be removed by etchback without first removing the gap fill nitride in the underlapped region. In other words, according to the second prior art, if a gap fill nitride is present in the underlapped region, a tightly spaced gap structure with a width less than twice the thickness of the deposited gap fill nitride layer also contains another gap fill nitride as well. According to both embodiments of the present invention, the gap fill nitride is present in the underlapping region, but is not present in any tightly spaced gap structure in the first semiconductor area 1 or in the second semiconductor area 2.

Typical thickness of a gap fill nitride layer is about 60 nm. According to both embodiments of the present invention, a tightly spaced gap structure is in a location selected from the group consisting of a first location between two substantially vertical walls of the first stress liner in the first semiconductor area and a second location between two substantially vertical walls of the second stress liner in the second semiconductor area, and may be less than 120 nm wide. The tightly spaced gap structure may be less than 90 nm wide, may further be less than 60 nm wide, or may even be less than 30 nm wide as long as the width is greater than 0 nm. However small the width of the tightly spaced gap structure may be, the gap fill nitride is not present in the tightly spaced gap structure in the first or second semiconductor area (1 or 2) since the tightly spaced gap structure is filled with either a first MOL dielectric 30 or a second MOL dielectric 40.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A semiconductor structure comprising:
a semiconductor substrate;
at least one first type MOSFET located in a first semiconductor area on said semiconductor substrate;
a first stress liner located directly on said at least one first type MOSFET;
at least one second type MOSFET located in a second semiconductor area on said semiconductor substrate;
a second stress liner located directly on said at least one second type MOSFET;
an underlapping region located between said first semiconductor area and said second semiconductor area, wherein neither said first liner nor said second liner is present;
a gap fill nitride located in said underlapping region; and
at least one tightly spaced gap structure in a location selected from the group consisting of a first location between two substantially vertical walls of said first stress liner in said first semiconductor area and a second location between two substantially vertical walls of said second stress liner in said second semiconductor area; wherein said at least one tightly spaced gap structure is less than 120 nm wide and is not filled with said gap fill nitride.

2. The semiconductor structure of claim 1, further comprising a portion of shallow trench isolation located underneath said gap fill nitride.

3. The semiconductor structure of claim 1, further comprising a gate line located underneath said gap fill nitride.

4. The semiconductor structure of claim 1, wherein one of said first stress liner and said second stress liner applies a compressive stress to structures therebeneath and the other of said first stress liner and said second stress liner applies a tensile stress to structures therebeneath.

5. The semiconductor structure of claim 4, further comprising:
a first middle-of-line (MOL) dielectric located directly on said first stress liner; and
a second middle-of-line (MOL) dielectric located directly on said first stress liner.

6. The semiconductor structure of claim 5, wherein said first stress liner comprises first silicon nitride, said second stress liner comprises second silicon nitride, said first MOL dielectric comprises first silicon oxide, and said second MOL dielectric comprises second silicon oxide.

7. The semiconductor structure of claim 6, wherein a first top surface of said first MOL dielectric is located above said first stress liner and a second top surface of said second MOL dielectric is located above said second stress liner.

8. The semiconductor structure of claim 7, further comprising an etch stop layer located directly on portions of said first MOL dielectric and directly on portions of said first stress liner.

9. The semiconductor structure of claim 8, wherein said etch stop layer is a silicon oxide layer.

10. A method of manufacturing a semiconductor structure comprising:
providing a semiconductor substrate;
forming at least one first type MOSFET in a first semiconductor area and at least one second type MOSFET in a second semiconductor area on said semiconductor substrate;
forming a first stack of a first stress liner and a first MOL dielectric directly on said at least one first type MOSFET in said first semiconductor area;
forming a second stack of a second stress liner and a second MOL dielectric directly on said at least one second type MOSFET in said second semiconductor area;
forming an underlapping region between said first semiconductor area and said second semiconductor area, wherein said underlapping region contains neither said first liner nor said second liner; and
forming a gap fill nitride in said underlapping region.

11. The method of claim 10, wherein a first top surface of said first MOL dielectric is formed above said first stress liner and a second top surface of said second MOL dielectric is formed above said second stress liner.

12. The method of claim 11, further comprising:
forming said first stress liner directly on said at least one first type MOSFET and directly on said at least one second type MOSFET; and
forming said second stress liner directly on said first MOL dielectric and directly on said at least one second type MOSFET.

13. The method of claim 12, further comprising planarizing said second MOL dielectric using a portion of said second stress liner in said first semiconductor area as a stopping layer.

14. The method of claim 13, wherein in said second stress liner is removed from said first semiconductor area.

15. The method of claim 14, wherein said first stress liner comprises first silicon nitride, said second stress liner comprises second silicon nitride, said first MOL dielectric comprises first silicon oxide, and said second MOL dielectric comprises second silicon oxide.

16. A method of manufacturing a semiconductor structure comprising:
providing a semiconductor substrate;
forming at least one first type MOSFET in a first semiconductor area and at least one second type MOSFET in a second semiconductor area on said semiconductor substrate;
forming a first stack of a first stress liner and a first MOL dielectric directly on said at least one first type MOSFET in said first semiconductor area;
forming an etch stop layer directly on a portion of said first stress liner;
forming a second stack of a second stress liner and a second MOL dielectric directly on said at least one second type MOSFET in said second semiconductor area;
forming an underlapping region between said first semiconductor area and said second semiconductor area, wherein said underlapping region contains neither said first liner nor said second liner; and
forming a gap fill nitride in said underlapping region.

17. The method of claim 16, wherein a second top surface of said second MOL dielectric is formed above said second stress liner.

18. The method of claim 16, further comprising:
forming said first stress liner directly on said at least one first type MOSFET and directly on said at least one second type MOSFET; and
forming said second stress liner directly on said etch stop layer and directly on said at least one second type MOSFET.

19. The method of claim 18, further comprising planarizing said first MOL dielectric using a portion of said first stress liner in said first semiconductor area as a stopping layer.

20. The method of claim 19, wherein in said second stress liner is removed from said first semiconductor area.
